(19) United States
(12) Patent Application Publication
(10) Pub. No.: US 2024/0347629 A1
(43) Pub. Date: Oct. 17, 2024

(54) HIGH-POWER COMPONENT BASED ON III NITRIDE COMPOUND SEMICONDUCTORS, INTERMEDIATE PRODUCT AND PROCESS FOR PRODUCTION OF A HIGH-POWER COMPONENT

(71) Applicant: Frauhofer-Gesellschaft zur Förderung der angewandten Forschung e.V., München (DE)

(72) Inventors: Philipp Döring, Freiburg (DE); Richard Reiner, Freiburg (DE)

(73) Assignee: Frauhofer-Gesellschaft zur Förderung der angewandten Forschung e.V., München (DE)

(21) Appl. No.: 18/636,343

(22) Filed: Apr. 16, 2024

(30) Foreign Application Priority Data
Apr. 17, 2023 (DE) 102023109595.1

(51) Int. Cl. H01L 29/778; H01L 21/02; H01L 29/423

(52) U.S. Cl. CPC H01L 29/7787; H01L 21/02362; H01L 21/02458; H01L 29/4232

(57) ABSTRACT

A high-power component (1) based on III nitride compound semiconductors, having at least one first, vertical transistor component (2) and at least one second component (10) having a lateral heterostructure (11). The lateral heterostructure (11) of the second component (10) is formed monolithically by selective epitaxial overgrowth on a subregion (4) of a surface (3) of the first, vertical component (2). The second component (10) has at least one transistor and optionally further active and/or passive components. An intermediate product (16) for the production of a high-power component (1) and to a process for the production of a high-power component (1) based on III nitride compound semiconductors are also provided.

### CROSS-REFERENCE TO RELATED APPLICATIONS

This application claims priority to German Patent Application No. 10 2023 109 595.1, filed Apr. 17, 2023, which is incorporated herein by reference as if fully set forth.

### TECHNICAL FIELD

The invention relates to a high-power component based on III nitride compound semiconductors and to an intermediate product for the production of a high-power component. The invention additionally also relates to a process for the production of a high-power component based on III nitride compound semiconductors.

### BACKGROUND

Components based on III nitride compound semiconductors have great potential in the field of high-power switching applications due to their particular physical properties compared to silicon-based or silicon carbide-based technologies. In particular, transistors with high electron mobility, so-called HEMTs, based on III nitride compound semiconductors, have already been commercially available for several years and are used in particular in the field of high-frequency or power electronics.

For example, the publication “A study on the Performance of AlGaN/GaN HEMTs Regrown on Mg-Implanted GaN Layers with low channel Thickness” (Döring et al., IEEE Transaction on Electron Devices, DOI 10.1109/TED.2023.3237803), discloses the production of AlGaN/GaN transistors having high electron mobility, where in a first step gallium nitride is produced on a silicon substrate and then subjected to magnesium implantation for p-type doping. This is followed by what is known as regrowth, in which are formed the heterostructures, in particular a so-called HEMT structure for particularly fast switching transistors on the substrate implanted with magnesium. This enables for example the production of large-area HEMT structures on large-area wafers as a starting point for the production of further transistor components.

It is furthermore known to produce large-area CAVETs with co-integrated HEMTs on the basis of gallium nitride, where here too a large-area gallium nitride layer is first produced and then implanted with magnesium to produce a thin p-type doped layer, the AlGaN/GaN heterostructure of the CAVET then being produced by regrowth on the substrate thus processed. (Technology of GaN-Based Large Area Cavets with Co-Integrated HEMTs, IEEE Transaction on Electron Devices, Vol. 68, No. 11, November 2021, Döring et al.).

While lateral high-power transistors based on gallium nitride technology are therefore already known and available on the market, the production of vertical components on the basis of III nitride compound semiconductors has to date been the subject of little investigation. This may in particular be due to the lack of native nitride substrates, meaning in particular that other substrates such as for example silicon carbide (SiC) or silicon (Si) have to be used instead.

In particular, the integration of vertical components with lateral components offers a multitude of control possibilities, in particular in the field of energy-efficient power electronics and especially in the field of future-relevant technologies such as electromobility, photovoltaics or wind power. In this respect, it is known in the prior art to bring vertical components and lateral components into contact with each other and join them using wafer bonding or hybrid integration methods. The effort for this and accordingly also the costs are very high. In addition, this type of construction techniques means that the components have large dimensions, and because of their size and weight it is not possible to use them in all technological fields. The reliability during operation can also be impaired, for example due to incompatible coefficients of thermal expansion.

In the field of vertical components, reliance is increasingly placed on the mentioned GaN-on-Si technology, in which vertical gallium nitride components are produced on silicon substrates, the silicon substrate being removed following completion of the component. A disadvantage here is that the quality of the gallium nitride is markedly worse due to the silicon substrate, compared to the use of other substrates such as sapphire or SiC. On the other hand, silicon substrates are cost-effective and available in large-area formats, which makes economical production possible accordingly.

In addition, it is also known in the prior art to produce a gallium nitride-based light-emitting diode on a metal oxide semiconductor field-effect transistor, what is known as a MOSFET, as described in the publication “Monolithic integration of GaN-based light-emitting diodes and metal-oxide semiconductor field-effect transistors”, Lee et. al., Optics Express A1589, 2014. In this case, however, the corresponding structures are first applied to the substrate over the entire surface and then individual regions are removed by means of selective etching in order to achieve the corresponding MOSFET structure with monolithically integrated light-emitting diode.

### SUMMARY

A problem addressed by the present application is that of specifying a high-power component, an intermediate product and a process for the production of a high-power component by which the production of a component with high blocking strength is made possible.

An additional problem addressed is that of specifying a high-power component, an intermediate product and a process for the production of a high-power component by which lateral and vertical transistor components can be easily integrated with each other.

This problem and further problems are solved by a high-power component having one or more of the features disclosed herein, an intermediate product for the production of a high-power component having one or more of the features disclosed herein related to the intermediate product, and by a process for the production of a high-power component also having one or more of the features disclosed herein.

Advantageous embodiments of the high-power component are set out below and in the claims. Further advantageous embodiments of the process for the production of a high-power component are also set out below and in the claims.

In particular, the high-power component is produced by a process for the production of a high-power component or an advantageous embodiment thereof. Furthermore, carrying out the process for the production of a high-power component or an advantageous embodiment thereof also results in a high-power component according to the invention or an advantageous embodiment thereof.

A first solution is provided by a high-power component based on III nitride compound semiconductors, which comprises at least one first, vertical transistor component and at least one second component having a lateral heterostructure, wherein the lateral heterostructure of the second component is formed monolithically by means of selective epitaxial overgrowth on a subregion of a surface of the vertical component, wherein the second component comprises at least one transistor and optionally at least one further active and/or passive component.

The at least one second component is thus formed only on a sub-area of the first vertical transistor component, as a result of which there is precisely no full-area overgrowth of the first vertical transistor component, as is effected for example in the case of CAVETS. It is advantageous in particular that both the vertical transistor component and the lateral component are formed monolithically, with a sub-area of the surface of the first vertical transistor component serving as a substrate for the formation of the second component with lateral heterostructure. In particular, it is possible with the high-power component according to the invention to dispense with a wafer bonding of vertical transistor component and lateral component, which in addition to at least one transistor optionally also comprises at least one active and/or passive component, with the quality of the component also being improved, especially as a result of a reduction in undesirable parasitic influences of the construction technology when bonding. Overall, the monolithic integration results in a reduction in the parasitic, capacitive and inductive effects, especially in the case of the second component. In addition, a higher energy efficiency and a higher area efficiency with regard to the production costs are achieved, since the high-power components according to the invention can be of a much smaller form. As a result, they are preferably usable in the field of energy-efficient power electronics, for example, but not exclusively, in the field of electromobility, photovoltaics or in wind power plants. Lastly, high current carrying capacities and low sheet resistances can be achieved with the high-power component according to the invention, as a result of which the high-power component according to the invention has a much higher efficiency and power density compared to the customary lateral GaN technology.

III or group III refers in general to the elements of the third main group of the periodic table. In particular, these are the elements aluminum (Al), gallium (Ga) and/or indium (In). Scandium (Sc) and/or yttrium (Y) may additionally also be included in the layer structures of the components. The III nitride compound semiconductors are semiconductors based on group III nitrides. These are in particular binary, ternary, quaternary or quinternary compound semiconductors such as for example gallium nitride (GaN), aluminum gallium nitride (AlGaN) or indium aluminum gallium nitride (InAlGaN).

The active component optionally comprising the second component may for example be one or more diodes and/or one or more sensors. The passive component optionally comprising the second component may for example be one or more capacitors, resistors, inductances and/or sensors. For example, the sensor may be a temperature-sensitive sensor. Combinations of the aforementioned active and/or passive components may also be included in the second component in addition to the at least one transistor.

In particular, the second component may constitute an integrated circuit.

The second component is preferably in the form of a transistor.

Optionally, the first transistor component may also comprise at least one further active and/or passive component.

In a preferred embodiment, both the first transistor component and the second component are formed on the basis of III nitride compound semiconductors. Thus, both the first transistor component and the second component are based on III nitride compound semiconductors, as a result of which components with a high blocking strength can be obtained and the physical and technical advantages of III nitride technology, such as for example a direct band gap of the compound semiconductors, can be utilized for the first transistor component and the second component.

It is a feature of a preferred embodiment of the high-power component that a two-dimensional electron gas is formed within the lateral heterostructure of the second component. The lateral heterostructure of the second component is thus produced such that within it is formed a two-dimensional electron gas that enables a very precise and reliable control of the second component even at frequencies in the range from 1 Hz to 100 GHz, preferably in the range from 50 Hz to 10 GHz.

It is a feature of a further preferred embodiment of the high-power component that a switching speed of the first transistor component lies in the range from 0.1 V/ns to 1000 V/ns, preferably in the range from 1 V/ns to 100 V/ns.

In an advantageous embodiment, the lateral heterostructure is based on AlGaN, AlN, ScAlGaN, InAlGaN and/or YAlGaN. The aforementioned materials are particularly suitable for the production of a lateral heterostructure for a high-quality second component, whereby good control and reliability of the second component can be achieved in the application.

In a particularly preferred embodiment, for the formation of the subregion on the surface of the first transistor component, a protective layer is formed outside of the subregion. The protective layer is thus used to form the subregion which is devoid of a protective layer and on which the second component is created after the protective layer has been formed. The protective layer can preferably be a high-temperature-stable protective layer. The use of a high-temperature-stable protective layer means that the latter is preserved even during overgrowth for the production of the second component and can thereafter be selectively removed.

In a particularly preferred embodiment, the protective layer is formed from a dielectric, in particular from silicon nitride or silicon oxide. A dielectric firstly can be easily applied to the surface of the first transistor component, and after the overgrowth and monolithic formation of the second component can also be removed correspondingly easily from the surface by means of selective etching, for example using KOH, without attacking or influencing the III nitride compound semiconductors in the process.

It is a feature of an advantageous embodiment that the high-power component has a blocking strength of greater than 200 V, preferably greater than 600 V, particularly preferably greater than 1 kV. A high blocking strength can be achieved in particular via the corresponding lateral heterostructure of the second component. As a result, the overall operational reliability of the high-power component is increased, which makes it preferably usable in the field of high-voltage applications, such as for example in electromobility, photovoltaics or wind power plants.

Advantageously, the first transistor component is devoid of a polarization-induced electron channel, whereby on account of the feasibility improved area-specific resistance can be achieved.

In a further preferred embodiment, the first transistor component comprises a plurality of layers, with preferably the uppermost layer, which forms the surface, of the first transistor component being n-type doped or p-type doped. A doped layer as the uppermost, surface-forming layer of the first transistor component serves in particular as a substrate for the second component. The doped layer enables corresponding electrical circuit possibilities and thus allows the second component to influence the first transistor component. The first transistor component can therefore accordingly be influenced and controlled via the uppermost doped layer depending on the configuration of the second component.

Alternatively or, preferably, in addition, a diffusion barrier is formed on the subregion between the first transistor component and the lateral heterostructure of the second component. The diffusion barrier prevents in particular dopants from diffusing into the lateral heterostructure of the second component during the overgrowth and formation of the lateral heterostructure or of the second component. In particular, the doping has a special influence on the formation of the components and their function, meaning that avoidance of diffusion should be achieved. As diffusion barrier, the material AlN or AlGaN is used in particular.

It is a feature of an advantageous embodiment of the high-power component that a source contact of the at least one transistor of the second component is formed extending into the first component, in particular into the uppermost layer of the first transistor component. Contacts of the second component can therefore also be used for controlling and influencing the first transistor component.

In a preferred embodiment, the first component is in the form of a MOSFET, trench MOSFET, DMOS, JFET, FinFET, OGFET or SIT. The first, vertical transistor component can therefore present a multitude of forms of the transistor, with the second component on the first transistor component being produced on the surface monolithically by overgrowth independently of the choice or configuration of the first transistor component.

The second component is advantageously in the form of an HEMT or comprises at least one HEMT. Preferably, the second component is in the form of a MOSHEMT or MISHEMT or comprises at least one corresponding element. HEMT structures have the advantage that they have a high blocking strength and are at the same time already used in a multitude of ways in the field of high-frequency or power electronics.

Alternatively or, preferably, in addition, the second component comprises a p gate, in particular a p-GaN gate, or recess gate, in order to be able to produce a normally off variant which is advantageous from a safety perspective and in which no current flows in the absence of a gate voltage.

In yet a further preferred embodiment, the second component is used as a cascade circuit for the first component. Amplification circuits can in particular be realized as a result. In particular, the first transistor component exhibits normally on behavior and the second component exhibits normally off behavior. The thus-configured high-power component then overall exhibits normally off behavior and is used in particular as a normally-off cascade.

Alternatively or, preferably, in addition, the second component is used as an integrated gate driver, current sensor and/or temperature sensor for the first transistor component. The second component can thus be used in a multitude of ways, depending on the lateral heterostructure and its exact configuration, and in particular can be utilized for switching or as a sensor for the first transistor component.

A further solution to the problem is provided by an intermediate product for the production of a high-power component as set out above or a preferred embodiment thereof, wherein the intermediate product comprises at least one first, vertical transistor component and a lateral heterostructure formed monolithically by means of epitaxy on a subregion of a surface of the first, vertical component, and, outside of the subregion of the surface of the first, vertical component, a protective layer, in particular a high-temperature-stable protective layer. This intermediate product can then be processed, for example, by removing the protective layer and further processing the lateral heterostructure by forming contacts to give the second component.

Yet a further solution to the problem is provided by a process for the production of a high-power component based on III nitride compound semiconductors, comprising the steps:
A) providing a substrate;
B) producing at least one first, vertical transistor component on the substrate by means of epitaxy;
C) selectively coating a surface of the first component with a protective layer up to a subregion;
D) producing a monolithic lateral heterostructure on the subregion by epitaxial overgrowth;
E) etching the protective layer; and
F) processing the heterostructure for formation of at least one second component with lateral heterostructure on the subregion of the first component, wherein the second component comprises at least one transistor and optionally at least one further active and/or passive component.

The process according to the invention produces a monolithically formed high-power component in which at least one vertical transistor component and at least one further, second component with lateral heterostructure, comprising at least one transistor and optionally at least one further active and/or passive component, are formed together, as a result of which it is possible to dispense with a wafer bonding or hybrid construction technique. This results in a high-power component of high quality, with the parasitic, capacitive and inductive effects, especially in the case of the second component, being reduced by the monolithic integration. In addition, a higher efficiency and a higher area efficiency are achieved, since according to the process of the invention only a subregion of the surface of the first transistor component is used for the second component and the components can be of smaller form overall as a result of the monolithic integration. Lastly, the high-power components produced by the process can have high current carrying capacities and low sheet resistances, as a result of which the high-power component according to the invention has a much higher efficiency and power density compared to the customary lateral GaN technology.

The at least one first transistor component can already have been fully processed after process step B), meaning that all essential elements of the transistor component are already present, for example also the contacts for source, drain and gate. The first transistor component is preferably present after process step B) in a form in which the first transistor component has already been structurally fully processed and only the contacts have not yet been fully formed. The formation and finishing of the first transistor component, in particular the formation of the contacts, is preferably effected in the course of processing the heterostructure to give the second component in process step F).

It is a feature of a preferred embodiment of the process that the first component is in the form of a MOSFET, trench MOSFET, DMOS, JFET, FinFET, OGFET or SIT. The first, vertical transistor component can therefore present a multitude of forms of the transistor, with the second component on the first transistor component being produced on the surface monolithically by overgrowth independently of the choice or configuration of the first transistor component.

Alternatively or, preferably, in addition, the second component is in the form of an HEMT or comprises an HEMT. The second component is particularly preferably in the form of a MOSHEMT or MISHEMT or comprises a corresponding element. HEMT structures have the advantage that they have a high blocking strength and are at the same time already used in a multitude of ways in the field of high-frequency or power electronics. Alternatively and particularly preferably, the second component is formed as comprising a p gate, in particular p-GaN gate, or recess gate.

In an advantageous embodiment, a diffusion barrier is applied to the subregion after process step C) and before process step D). The diffusion barrier prevents in particular dopants from diffusing into the lateral heterostructure of the second component during the overgrowth and formation of the lateral heterostructure or of the second component.

It is a feature of a preferred embodiment that the substrate used is sapphire, silicon, SiC, GaN or a ceramic. Silicon in particular is available cost-effectively in large-area formats. The use of sapphire, SiC or GaN enables the formation of high-quality layers based on the III nitride compound semiconductors, although GaN substrates in particular are very expensive and available in only small formats.

Process step F) is advantageously effected before process step E). The processing of the heterostructure for the formation of a second component can therefore also be effected before the etching of the protective layer, as a result of which the surface of the first transistor component is protected further during the processing.

Alternatively or, preferably, in addition, an intermediate product is present after process step D) or after process step E). The intermediate product thus preferably comprises the at least one first vertical transistor component and the lateral heterostructure for the second component.

In a preferred embodiment, the epitaxy is effected by means of metal-organic chemical vapor deposition (MOCVD) or molecular beam epitaxy (MBE). This makes it possible to achieve high-quality high-power components with high-quality layers and thus less influence due to defects in the crystal structure.

### BRIEF DESCRIPTION OF THE DRAWINGS

Further advantageous features and configurations are elucidated hereinafter on the basis of exemplary embodiments and the figures. In the figures:

FIGS. 1A to 1C show various points in the course of the process for the production of a high-power component;

FIG. 2 shows an embodiment of a high-power component according to the invention;

FIG. 3 shows a further embodiment of a high-power component according to the invention;

FIG. 4 shows yet a further embodiment of a high-power component according to the invention; and

FIG. 5 shows yet a further embodiment of a high-power component according to the invention.

### DETAILED DESCRIPTION

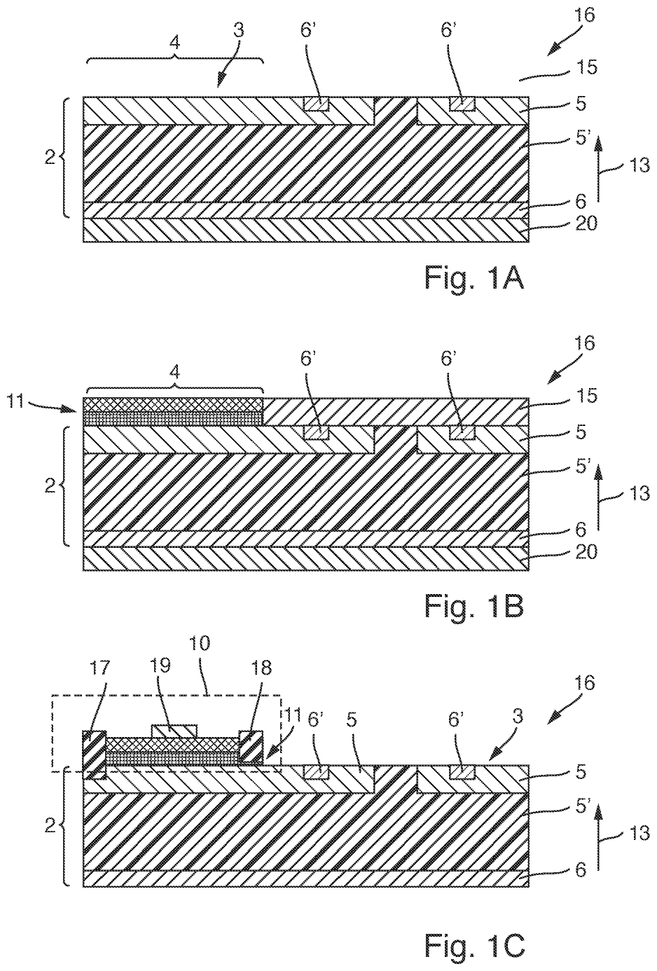

FIGS. 1A to 1C respectively show various stages in the performance of the process of the invention for the production of a high-power component 1.

FIG. 1A shows an intermediate product 16 in the course of the production of a high-power component 1 after process step C). For the production of the intermediate product 16 shown in the figure, a substrate 20 made of silicon was provided beforehand in a process step A), on which in a process step B) a first vertical transistor component 2 was produced by means of epitaxy on the basis of III nitride compound semiconductors. The epitaxy was effected in a system by means of metal-organic chemical vapor deposition (MOCVD). Alternatively, such structures can also be produced by means of molecular beam epitaxy (MBE).

The first transistor component 2 comprises a contact layer 6 formed on the substrate 20 and a plurality of layers 5, 5′, which were produced on the contact layer 6 essentially over the entire surface. The uppermost layer 5 of the first transistor component 2, and thus essentially forming the surface 3 of the first transistor component 2, is formed as p-type doped GaN. The further layer 5′ serves as a drift zone and consists of n-type doped GaN. Furthermore, within the uppermost layer 5, contact areas 6′ made from n-type doped GaN were formed, these being formed for the contacting of source and gate of the first transistor component 2. The processing of the first transistor component 2 is complete here in so far as that only corresponding contacts at source, drain and gate have not yet been fully formed. Structurally, therefore, the first transistor component 2 has in terms of its construction been fully processed except for the contacts.

In the course of the production of a high-power component 1, a protective layer 15 in the form of a dielectric, in the present case silicon oxide, was applied to the surface 3 of the first, vertical transistor component 2 in a process step C). The protective layer 15 does not cover the entire surface 3 of the first transistor component 2, but has been applied only selectively to the surface 3, with a subregion 4 being omitted.

In a process step D), a lateral heterostructure 11 likewise on the basis of III nitride compound semiconductors is then applied monolithically to the subregion 4 in the course of overgrowth by means of MOCVD or another epitaxial growth method. The lateral heterostructure 11 likewise comprises a plurality of layers, these layers being formed in such a way that a two-dimensional electron gas 12 forms in the lateral heterostructure 11. The subregion 4 thus serves as a substrate for the formation of the lateral heterostructure 11. The lateral heterostructure 11 has, inter alia, the following structure: On the surface 3 of the subregion 4, a barrier on the basis of a III nitride is formed, the barrier consisting of a compound with a larger band gap than the underlying III nitride. Passivation layers are additionally applied, in particular silicon nitride (SiN) or another nitridic compound that is not electrically conductive.

In contrast to the formation of CAVETS, the second component 10 is formed only on a sub-area 4 of the first vertical transistor component 2. There is thus precisely no complete overgrowth of the first vertical transistor component 2 effected. The monolithic formation of the lateral heterostructure 11 on the sub-area 4 improves the overall quality of the resulting high-power component 1, since parasitic, capacitive and inductive effects are reduced in the second component 10. This leads firstly to a higher efficiency and secondly also to a higher area efficiency, since the high-power component 1 according to the invention can be formed to be markedly smaller compared with the wafer bonding known from the prior art.

After the overgrowth for production of the lateral heterostructure 11 on the subregion 4 of the first transistor component 2, an intermediate product 16 is then present, as shown in FIG. 1B. During the overgrowth, the lateral heterostructure 11 can also be formed extending beyond a thickness of the protective layer 15 in the thickness direction 13, with precisely no growth being effected on the protective layer 15 during the epitaxy by means of MOCVD.

Following the formation of the lateral heterostructure 11, the processing of the heterostructure 11 to give a second component 10 is effected in a process step F), with at least one transistor with corresponding source contact 17, drain contact 18 and gate contact 19 being formed accordingly for this purpose, as is shown in FIG. 1C. During the processing to give the second component 10, further active and/or passive components, such as for example diodes, sensors, resistors, inductances and/or capacitors, can optionally additionally also be formed. As a result of the processing, in the present case at least one transistor with high electron mobility, what is known as an HEMT, is formed from the lateral heterostructure 11. The source contact 17 of the transistor of the second component 10 is configured in such a way here that it is brought into contact with the uppermost layer 5 of the first transistor component 2. Control of the first transistor component 2 is thus made possible via the second component 10.

In addition to the processing of the lateral heterostructure 11, the protective layer 15 has previously been removed in a process step E) by means of selective etching, in the present case by means of KOH, so that the surface 3 of the first transistor component 2 covered by means of the protective layer 15 has been exposed again. After etching of the protective layer 15, the source contact 7, the gate contact 9 and the drain contact 8 of the first transistor component 2 are also formed in the course of the processing of the second component 10. For this purpose, inter alia, the substrate 20 was completely detached, so that the drain contact 8 could be formed over the entire surface of the contact layer 6. The high-power component 1 is particularly suitable for use in the field of electromobility, since high current carrying capacities and low sheet resistances can be achieved by the construction of the invention, in particular by the monolithic integration of the second component 10, resulting in a much higher efficiency and power density being achieved compared to the customary lateral GaN technology.

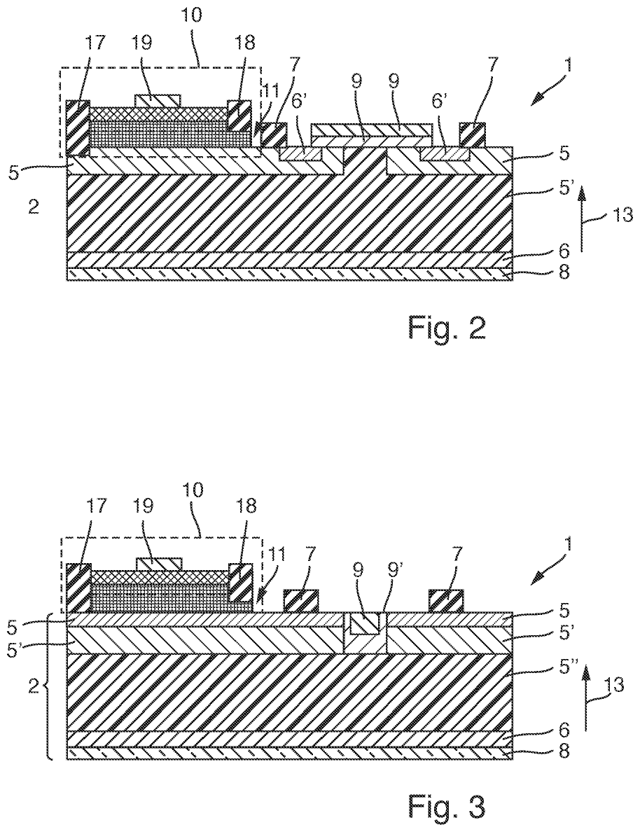

The following FIGS. 2 to 5 show various embodiments of high-power components 1 according to the invention.

FIG. 2 shows a high-power component 1 formed from a first transistor component 2 in the form of a DMOS and a second component 10 comprising at least one HEMT formed by overgrowth on the subregion 4 of the surface 3 of the first transistor component 2. The construction of the first transistor component 2 and the second component 10 essentially originates from the production process described and illustrated in FIGS. 1A to 1C, with the first transistor component 2 and the second component 10 being formed on the basis of the group III nitride compound semiconductors. Within the second component 10, a two-dimensional electron gas 12 is formed by the lateral heterostructure 11, as a result of which very precise and reliable control of the second component 10 is made possible even at high frequencies in the gigahertz range. Contacting of the two-dimensional electron gas 12 is effected via the source contact 17 and the drain contact 18. The source contact 17 of the transistor of the second component 10 is additionally formed extending into the uppermost layer 5 of the first transistor component 2, again in the form of a p-type doped layer 5. The properties of the first transistor component 2 can thus also be influenced and controlled via the second component 10. The source contacts 7 are formed as ohmic contacts. A gate insulator 9′, for example made of silicon nitride or aluminum oxide, is formed between the gate contact 9 and the surface 3 of the first transistor component 2. The blocking strength of this high-power component 1 is particularly high and exceeds 1 kV. This form of the high-power component 1 with a DMOS as first transistor component 2 is particularly suitable as a high-voltage converter and is used, for example, in the automotive sector.

FIG. 3 shows a further embodiment of the high-power component 1 according to the invention, in which the first, vertical transistor component 2 is present in the form of a MOSFET. In this case, the surface 3 of the MOSFET is formed as first transistor component 2 by an n-type doped layer 5, on which, in turn, on a subregion 4, a second component 10 has been formed at least comprising an HEMT. Below the uppermost layer 5 of the first transistor component 2, a p-type doped layer is formed as a current blocking layer 5′. The source contact 17 of the transistor of the second component 10 is formed in this case only up to the surface 3 of the first transistor component 2 and thus up to the layer 5. The gate contact 9 of the first transistor component 2 is embedded in a gate insulator 9′, which is formed within the layer 5. This form of the high-power component 1 with a MOSFET as first transistor component 2 is also particularly suitable as a high-voltage converter and is used, for example, in the automotive sector.

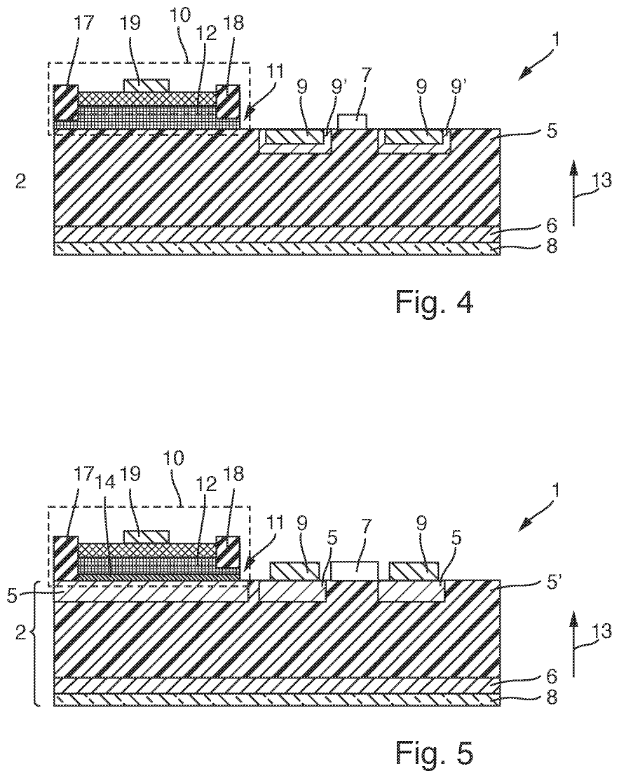

FIG. 4 shows yet a further form of the high-power component 1. Compared to the above embodiments of the high-power component 1, this form differs essentially in the configuration of the first transistor component 2, which is in the form of a FinFET. The second component 10 is in turn formed as comprising an HEMT, wherein the source contact 17 and the drain contact 18 are only in direct contact with the lateral heterostructure 11 and form a contact to the two-dimensional electron gas 12. This form of the high-power component 1 with a FinFET as first transistor component 2 is also particularly suitable as a high-voltage converter and is used, for example, in the automotive sector.

FIG. 5 shows yet a further form of the high-power component 1. Compared to the above embodiments of the high-power component 1, this form differs essentially in the configuration of the first transistor component 2, which in the present case is in the form of a JFET. The second component 10 is in turn formed as comprising an HEMT, the source contact 17 being in contact with the surface 3 and thus the uppermost layer 5 of the first transistor component 2. The drain contact 18 is only in contact with the lateral heterostructure 11 and, together with the source contact 18, allows contacting of the two-dimensional electron gas 12. The uppermost layer 5 of the first transistor component 2, which is in turn formed as p-type doped layer 5, is formed only in sections. The regions of the p-type doped uppermost layer 5 are arranged essentially below the lateral heterostructure 11 of the second component 10 and below the gate contacts 9. In addition, a diffusion barrier 4 is formed on the surface 3 of the subregion 14 of the first transistor component 2 and thus below the lateral heterostructure 11. This form of the high-power component 1 with a JFET as first transistor component 2 is also particularly suitable as a high-voltage converter and is used, for example, in the automotive sector.

### LIST OF REFERENCE SIGNS

1 high-power component
2 first transistor component
3 surface
4 subregion
5, 5° layer
6 contact layer
6′ contact area
7 source contact
8 drain contact
9 gate contact
9′ gate insulator
10 second component
11 heterostructure
12 electron gas
13 thickness direction
14 diffusion barrier
15 protective layer
16 intermediate product
17 source contact
18 drain contact
19 gate contact
20 substrate

1. A high-power component (1) based on III nitride compound semiconductors, comprising:
at least one first, vertical transistor component (2) and at least one second component (10) having a lateral heterostructure (11);
the lateral heterostructure (11) of the second component (10) is formed monolithically by selective epitaxial overgrowth on a subregion (4) of a surface (3) of the first, vertical component (2); and
the second component (10) comprises at least one transistor and at least one further active and/or passive component.

2. The high-power component (1) as claimed in claim 1, wherein both the first transistor component (2) and the second component (10) are formed based on III nitride compound semiconductors.

3. The high-power component (1) as claimed in claim 1, further comprising a two-dimensional electron gas (12) formed within the lateral heterostructure (11) of the second component (10).

4. The high-power component (1) as claimed in claim 1, wherein the lateral heterostructure (11) is based on AlGaN, AlN, ScAlGaN, InAlGaN and/or YAlGaN.

5. The high-power component (1) as claimed in claim 1, wherein, for formation of the subregion (4) on the surface (3) of the first transistor component (2), a protective layer (15) is formed outside of the subregion (4).

6. The high-power component (1) as claimed in claim 5, wherein the protective layer (15) is formed from a dielectric.

7. The high-power component (1) as claimed in claim 1, wherein the high-power component (1) has a blocking strength of greater than 200 V.

8. The high-power component (1) as claimed in claim 1, wherein the first component (2) is devoid of a polarization-induced electron channel.

9. The high-power component (1) as claimed in claim 1, wherein the first component (2) comprises a plurality of layers (5, 5′), with an uppermost layer, which forms the surface (3), of the first component (2) being n-type or p-type doped.

10. The high-power component (1) as claimed in claim 1, further comprising a diffusion barrier (14) formed on the subregion (4) between the first component (2) and the lateral heterostructure (11) of the second component (10).

11. The high-power component (1) as claimed in claim 1, wherein a source contact (17) of the transistor of the second component (10) is formed extending into the first component (2).

12. The high-power component (1) as claimed in claim 1, wherein the first component (2) comprises a MOSFET, trench MOSFET, DMOS, JFET, FinFET, OGFET or SIT.

13. The high-power component (1) as claimed in claim 1, wherein the second component (10) comprises at least one of an HEMT, a MOSHEMT or MISHEMT, a p gate, or a recess gate.

14. The high-power component (1) as claimed in claim 1, wherein the second component (10) is used as a cascade circuit for the first component (2).

15. The high-power component (1) as claimed in claim 1, wherein the second component (10) is used as at least one of an integrated gate driver, current sensor, or a temperature sensor.

16. An intermediate product (16) for the production of a high-power component (1), the intermediate product (16) comprises:
a first, vertical transistor component (2);
a lateral heterostructure (11) formed monolithically by epitaxy on a subregion (4) of a surface (3) of the first, vertical component (2); and,
outside of the subregion (4) of the surface (3) of the first, vertical component (2), a protective layer (15).

17. A process for the production of a high-power component (1) based on III nitride compound semiconductors, the process comprising:
A) providing a substrate (20);
B) producing at least one first, vertical transistor component (2) on the substrate (20) by epitaxy;
C) selectively coating a surface (3) of the first component (2) with a protective layer (15) up to a subregion (4);
D) producing a monolithic lateral heterostructure (11) on the subregion (4) by epitaxial overgrowth;
E) etching the protective layer (15); and
F) processing the heterostructure (11) for formation of at least one second component (10) with the lateral heterostructure (11) on the subregion (4) of the first component (2), wherein the second component (10) comprises at least one transistor and at least one further active and/or passive components.

18. The process as claimed in claim 17, wherein at least one of a) the first component (2) comprises a MOSFET, trench MOSFET, DMOS, JFET, FinFET, OGFET or SIT, or b) the second component (10) comprises at least one of an HEMT, a MOSHEM or MISHEMT, a p gate, or a recess gate.

19. The process as claimed in claim 17, wherein a diffusion barrier (14) is applied to the subregion (4) after process step C) and before process step D).

20. The process as claimed in claim 17, wherein the substrate (20) is sapphire, silicon, SiC, GaN or a ceramic.

21. The process as claimed in claim 17, wherein at least one of a) process step F) is effected before process step E), or b) an intermediate product (16) is present after process step D) or process step E).

22. The process as claimed in claim 17, wherein the epitaxy is effected by metal-organic chemical vapor deposition (MOCVD) or molecular beam epitaxy (MBE).
